(19) United States
(12) Patent Application Publication
(10) Pub. No.: US 2024/0125976 A1
(43) Pub. Date: Apr. 18, 2024

(54) DISTRIBUTED OPTIMIZATION FOR METASURFACE DEVELOPMENT

(71) Applicant: QUANTINUUM LLC, Broomfield, CO (US)

(72) Inventors: Adam Jay OLLANIK, Boulder, CO (US); David M. GAUDIOSI, Broomfield, CO (US)

(21) Appl. No.: 18/486,262

(22) Filed: Oct. 13, 2023

Related U.S. Application Data
(60) Provisional application No. 63/379,992, filed on Oct. 18, 2022.

(51) Int. Cl. G02B 1/00; G02F 1/00; G06F 30/20

(52) U.S. Cl. CPC G02B 1/002; G02F 1/0063; G02F 1/0081; G06F 30/20; G02F 2202/30

(57) ABSTRACT

A method for designing a metasurface is provided. The method may include selecting a first metamaterial structure of a plurality of metamaterial structures of the metasurface; generating a forward light propagation model for the first metamaterial structure; generating a reciprocal light propagation model for the first metamaterial structure using a light manipulation function for the metasurface; determining a first electromagnetic response difference between the forward light propagation model and the reciprocal light propagation model; and determining a first property range of the first metamaterial structure such that the first electromagnetic response difference is optimized.

### CROSS-REFERENCE TO RELATED APPLICATIONS

This application claims priority to U.S. Application No. 63/379,992, filed Oct. 18, 2022, the contents of which are incorporated herein by reference in their entireties.

### TECHNICAL FIELD

Various embodiments are related to apparatuses, systems, and methods relating to optimization in developing metasurface that can be used in signal manipulation for example for changing a property of light beams and/or electromagnetic waves.

### BACKGROUND

When developing a metasurface, modeling every individual metasurface element in the final metasurface array can be computationally expensive. Therefore, the effects of metasurface elements are typically modeled during a library generation step prior to modeling the final metasurface phased array. However, metasurface elements can perform differently in phased arrays than in a library generation modeling. Metasurface optics or wave performance can be impacted or degraded due to the discrepancies between the in phased arrays functioning versus the library generation modeling. Through applied effort, ingenuity, and innovation many deficiencies of such systems have been solved by developing solutions that are structured in accordance with the embodiments of the present invention, many examples of which are described in detail herein.

### BRIEF SUMMARY OF EXAMPLE EMBODIMENTS

Example embodiments provide methods, systems, apparatuses, computer program products and/or the like for designing a metasurface. In an example embodiment, the method includes selecting a first metamaterial structure of a plurality of metamaterial structures of the metasurface; generating a forward light propagation model for the first metamaterial structure using a light manipulation function for the metasurface; generating a reciprocal light propagation model for the first metamaterial structure using the light manipulation function for the metasurface; determining a first phase delay difference in the forward light propagation model and the reciprocal light propagation model; and determining a first property range of the first metamaterial structure such that the first phase delay difference is optimized.

In an example embodiment, the light manipulation function of the metasurface comprises any of refractive and/or reflective light manipulation function.

In an example embodiment, the reciprocal light propagation model models an interaction of light propagating in a reversed direction with the first metamaterial structure and the forward light propagation model models the interaction of light propagating in a forward direction with the first metamaterial structure, wherein in the forward light propagation model a forward angle of light remains unchanged and in the reciprocal light propagation model a reciprocal angle of light remains unchanged, wherein the reciprocal angle is determined using the light manipulation function for the metasurface and the forward angle.

In an example embodiment, the refractive or reflective light manipulation comprises a light focusing and/or collimating function.

In an example embodiment, the method further comprises determining a first amplitude difference in the forward light propagation model and the reciprocal light propagation model; and determining the first property range of the first metamaterial structure such that the first amplitude difference is optimized.

In an example embodiment, the method further comprises determining a first polarization difference in the forward light propagation model and the reciprocal light propagation model; and determining the first property range of the first metamaterial structure such that the first polarization difference is optimized.

In an example embodiment, first property range of the first metamaterial structure comprises any of a first shape and/or dimensions range of the first metamaterial structure. In an example embodiment, the first metamaterial structure is located at a periphery of the metasurface.

In an example embodiment, the method further comprises selecting a second metamaterial structure of a plurality of metamaterial structures; generating the forward light propagation model for the second metamaterial structure; generating the reciprocal light propagation model for the second metamaterial structure using the light manipulation function for the metasurface; determining a second phase delay difference in the forward light propagation model and the reciprocal light propagation model; and determining a second property range of the second metamaterial structure such that the second phase delay difference is optimized.

In an example embodiment, the method further comprises determining a first property value within the first property range, and a first location for the first metamaterial structure on a first unit cell of the metasurface; and determining a second property value within the second property range, and a second location for the second metamaterial structure on a second unit cell adjacent to the first unit cell, wherein the first and second property values and locations are determined to meet geometrical constraints of the metasurface.

In an example embodiment, the geometrical constraints comprise any of a distance between the first and second metamaterial structures and/or a fill fraction of a local region.

An embodiment herein provides an apparatus comprising at least one processor and a memory storing computer-executable instructions, the computer-executable instructions configured, when executed by the at least one processor, to cause the apparatus to perform the method of any of the embodiments described above.

An embodiment herein provides a computer program product comprising at least one non-transitory computer-readable medium storing computer-executable instructions, the computer-executable instructions configured, when executed by a processor of an apparatus, to cause the apparatus to perform the method of any of the embodiments described above.

Example embodiments provide a method for designing a metasurface, the method comprising: selecting a reference metamaterial structure of a plurality of metamaterial structures of the metasurface; determine a reference forward phase delay versus a property of the reference metamaterial structure for a forward incident angle; determine a reference reciprocal phase delay versus the property of the reference metamaterial structure for a reverse incident angle; and determine the property of the reference metamaterial structure such that a difference between the forward phase delay and the reciprocal phase delay is optimized, wherein the forward phase delay and the reciprocal phase delay are offset with a fixed phase value.

In an example embodiment, the method comprises determining the forward incident angle and the reverse incident angle using a phase mask of the metasurface. In an example embodiment, the method comprises determining the phase mask of the metasurface using a light manipulation function for the metasurface.

In an example embodiment, the method comprises selecting the reference metamaterial structure such that a difference between the forward incident angle and the reciprocal incident angle is minimized. In an example embodiment, the method comprises determining properties of another metamaterial structure by referencing a forward phase delay of the other metamaterial structure with the reference forward phase delay and refencing the reverse phase delay of the other metamaterial structure with the reference reverse phase delay.

In an example embodiment, the method comprises iteratively repeating the determining properties of other metamaterial structures until the metasurface is optimized.

Example embodiments provide a method for designing a metasurface, the method comprising: determining an optical response of a metamaterial structure of the metasurface for each value of the values for one or more placement parameters of the metamaterial structure, while keeping one or more global parameters of the metamaterial structure constant; determining, for each of the values of the one or more placement parameters, the optical response of the metamaterial structure for each value of the values for one or more shape parameters of the metamaterial structure, while keeping the one or more global parameters of the metamaterial structure constant; and recording the optical response with respect to each of the values of the one or more placement parameters and each of the one or more shape parameters.

In an example embodiment, the method comprises keeping the global parameters constant for all the metamaterial structures of the metasurface. In an example embodiment, the global parameters comprise height, local fill fraction, and/or wavelength associated with each metamaterial structure.

In an example embodiment, the placement parameters comprise: a forward incident angle of a forward optical beam on the metamaterial structure of the metasurface, wherein the forward incident angle is determined using an optical manipulation function of the metasurface; and a reciprocal incident angle of a reciprocal optical beam on the metamaterial structure of the metasurface, wherein the reciprocal incident angle of the optical beam is determined using the optical manipulation function of the metasurface.

In an example embodiment, the placement parameters comprise: a forward polarization of the forward optical beam on the metamaterial structure of the metasurface, wherein the forward polarization is determined using the optical manipulation function of the metasurface; and a reciprocal polarization of the reciprocal optical beam on the metamaterial structure of the metasurface, wherein the reciprocal polarization is determined using the optical manipulation function of the metasurface.

In an example embodiment, the method comprises: updating a metasurface master library using by recording the optical response with respect to each of the values of the one or more placement parameters and each of the one or more shape parameters; and optimizing the metasurface in the forward and reciprocal directions using the master library by determining optimum values of the one or more placement parameters and optimum values of the one or more shape parameters that optimize an aggregate metric for the metasurface.

Example embodiments provide a method for designing a metasurface, the method comprising: determining a forward transform function for one or more metamaterial structures of the metasurface; determining a reciprocal transform function for the one or more metamaterial structures of the metasurface; calculating a forward transformed beam by transforming a field of a forward incident beam according to the forward transform function; calculating a reciprocal transformed beam by transforming a field of a reciprocal incident beam according to the reciprocal transform function; comparing the forward transformed beam with a forward target beam and determine a forward gradient using the comparison; comparing the reciprocal transformed beam with a reciprocal target beam and determine a reciprocal gradient using the comparison; and modifying one or more shape parameters of metamaterial structures of the metasurface using the forward gradient and the reciprocal gradient.

In an example embodiment, the forward gradient maps to a forward shape gradient in one or more shape parameters of the one or more metamaterial structures of the metasurface and the reciprocal gradient maps to a reciprocal shape gradient in one or more shape parameters of the one or more metamaterial structures of the metasurface.

In an example embodiment, the method comprises: determining forward shape parameters of the metamaterial structures of the metasurface using the forward gradient; determining reverse shape parameters of the metamaterial structures of the metasurface using the reverse gradient; determining a shape convergence gradient, wherein the shape convergence gradient is a difference between the forward shape parameters and the reciprocal shape parameters for each metamaterial structure of the metasurface; and iteratively repeating the determining of the forward and reverse shape parameters, and determining the shape convergence gradient for each metamaterial structure of the metasurface until a difference between forward transformed beam and the forward target beam is optimized and a difference between reciprocal transformed beam with and the reciprocal target beam is optimized.

In an example embodiment, the method comprises optimizing the design of the metasurface by modifying the one or more metamaterial structures of the metasurface using the forward gradient and the reciprocal gradient such that a difference between forward transformed beam and the forward target beam is optimized and a difference between reciprocal transformed beam with and the reciprocal target beam is optimized. In an example embodiment, the modification comprises modifying the forward and reciprocal shape parameters.

In an example embodiment, the method comprises: minimizing the shape convergence gradient; prioritizing the minimizing of the shape convergence gradient in iteratively repeating the determining of the forward and reverse shape parameters; and finalizing the optimization when the shape convergence gradient for each metamaterial structure of the metasurface is zero.

In an example embodiment, the method comprises equating forward shape parameters of the metamaterial structures of the metasurface with the reciprocal shape parameters of the metamaterial structures of the metasurface.

In an example embodiment, the method comprises optimizing the design of the metasurface by modifying the one or more metamaterial structures of the metasurface using the forward gradient and the reciprocal gradient such that a combination of the forward gradient and the reciprocal gradient is minimized.

In an example embodiment, the modification of the one or more metamaterial structures of the metasurface comprises modifying the equal forward and reciprocal shape parameters of each metamaterial structure of the metasurface. In an example embodiment, the combination is a weighted average of the forward gradient and the reciprocal gradient.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a schematic diagram illustrating a metasurface, according to an example embodiment.

FIG. 2 is a schematic diagram illustrating a forward light propagation model for a metasurface, according to an example embodiment.

FIG. 3 is a schematic diagram illustrating a reciprocal light propagation model for a metasurface, according to an example embodiment.

FIG. 4A is a schematic diagram illustrating a forward light propagation model for a metamaterial structure, according to an example embodiment.

FIG. 4B is a schematic diagram illustrating a reciprocal light propagation model for a metamaterial structure, according to an example embodiment.

FIG. 5 is a schematic diagram illustrating a metasurface, according to an example embodiment.

FIG. 6 is a flowchart illustrating a method, according to an example embodiment.

FIG. 7 is a flowchart illustrating a method, according to an example embodiment.

FIG. 8 is a flowchart illustrating a method, according to an example embodiment.

FIG. 9 is a flowchart illustrating a method, according to an example embodiment.

FIG. 10 is a flowchart illustrating a method, according to an example embodiment.

FIG. 11 is a flowchart illustrating a method, according to an example embodiment.

FIG. 12 is a schematic diagram of an example computing entity that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative,” “exemplary” and/or “example” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

Metasurfaces may include an array of metamaterial structures (or elements) each disposed in a unit cell of the metasurface. The metamaterial structures may each have a unique set of properties. The set of properties may include any of the mechanical and/or electro-magnetic properties of the metamaterial structure such as height, local area fill fraction, wavelength, polarization, forward or reciprocal light beam angles (elevation and azimuth), and/or cross-sectional shape, etc.

In various embodiments, each metamaterial structure may manipulate an electro-magnetic property of an incident signal using an electro-magnetic response of the metamaterial structure. For example, a metamaterial structure may manipulate any of a phase, amplitude, and/or polarization of an incident signal in a unique way. In various embodiments, the electro-magnetic response of a metamaterial structure may include a linear and/or non-linear interaction with the incident signal, providing frequency shifts or frequency generation. Accumulatively, the metamaterial structures, may provide a light manipulation function on the incident signal.

In various approaches that have been used, a phase provided by a metamaterial structure is mapped to a parameter of a metamaterial structure, for example a diameter of a cylindrical metamaterial structure. Therefore, a single unit cell and a single shape of a metamaterial structure within the unit cell may be modeled. The modeled library therefore may provide a diameter needed to provide the phase shift required for the metamaterial structure for achieving the light manipulation function of the metasurface.

The generated library may provide the electromagnetic response of the metamaterial structure based on various properties of the metamaterial structure. Using a required light manipulation function for the metasurface, a computing entity may determine the electromagnetic response of the metamaterial structure and using the modeled library, the computing entity determines the physical and/or electromagnetic properties of the metamaterial structure. In an example, the library may include a set of phase, amplitude, and/or polarization modifiers, a mapping, or a complex number corresponding to each metamaterial structure that is multiplied to an input electromagnetic field to determine the output electromagnetic field generated by the metamaterial structure.

In an example, the light manipulation function of the metasurface may include the electromagnetic response of the metasurface. The light manipulation function therefore may describe how an input light beam is transformed by the metasurface in either forward and/or reciprocal directions. In various embodiments, a phase curvature of the metasurface may be determined using the light manipulation function of the metasurface. The phase curvature may include the phase transformation that each point on the metasurface needs to provide to an input optical beam to perform the light manipulation function. For example, when the light manipulation function of the metasurface is focusing in the forward direction and collimating in the reciprocal direction, the phase curvature of the metasurface provides the phase manipulation needed at each point on the metasurface to provide the focusing and collimation functions at the corresponding directions. A phase mask may refer to the discretized values of the phase curvature at each unit cell. Therefore, the phase mask of the metasurface provides the phase manipulation value each metamaterial structure needs to provide on the forward and/or reciprocal optical beam to provide the light manipulation function of the metasurface at the corresponding direction.

The metasurface may be developed and/or designed using an optimization method taking into account various properties of each of the metamaterial structures. For example, one or more properties of a metasurface to be formed and/or fabricated is determined through performance of an optimization method. These properties of the metamaterial structures may be described in the modeled libraries. In an example embodiment, the modeled library is generated during the optimization process or may be generated before the optimization process.

For example, a metamaterial structure model that incorporates the relevant properties (e.g., material properties of the metamaterial structure, geometric properties of the metamaterial structure, electromagnetic properties of the of the metamaterial structure, etc.) may be generated and/or determined (e.g., by a computing entity) for a new metamaterial structure of the metasurface during the optimization, design, and/or devolvement of the metasurface. The metamaterial structure model may then be added to the modeled library (e.g., stored in memory of the computing entity) for future use the next time a similar metamaterial structure and/or element is added to the optimization, design, and/or devolvement of the metasurface.

In various embodiments, using the modeled library and the phase mask of the metasurface, one or more properties of the metamaterial structure may be determined to arrive at a design of the metasurface.

However, while generating the library by modeling each single unit cell with periodic boundary conditions may not be computationally expensive, metamaterial structures may perform differently in the phased array when disposed on the metasurface than in the generated library model. An example cause of this discrepancy may be the fact that neighboring metamaterial structures on a metasurface may not be all uniform in practice. Another example cause for this discrepancy is because interaction with two different angles of beam, wave, or signal incidence may not be accounted for in the library modeling.

Therefore, unless the metasurface is uniform (e.g. includes uniform properties such as disposing of all the metamaterial structures where all the neighboring metamaterial structures are identical) and/or all angles of forward and reciprocal beams are similar, the metasurface may not perform similar as the library model indicates when disposed with varying properties on the metasurface.

For example, when there are variable fill fractions of the unit cells, or when neighboring metamaterial structures have different shapes or locations in the unit cell, etc., the geometric refractive index or the near field coupling of the elements may change. Therefore, if such library modeling alone is used to determine the array of metamaterial structures, the performance of the resulting metasurface may be degraded.

When using the modeled library in developing and optimizing a metasurface, it should be considered that variable fill fraction or fill factor of adjacent unit cells may result in a variable near field coupling of the adjacent metamaterial structures in those cells, which may impact the local effective refractive index of the metasurface. Considering all these variations into the optimization and development of the metasurface may make the full metasurface optimization computationally expensive, such that modeling may need to be limited to a small area metasurfaces. Thus, technical problems exist relating to the design of metasurfaces. For example, technical problems exist regarding being able to sufficiently model the properties of metasurfaces and the response of the metasurface to an incident beam to design a metasurface with an accurate response that is computationally tractable.

Various embodiments provide technical solutions to these technical problems. For example, in various embodiments, a distributed optimization strategy, using element-by-element inverse design and reciprocal modeling is used to design and develop the metamaterial structures. In various embodiments, a multi-dimensional library is generated and/or optimized using an iterative process. In various embodiments, an aggregate optimization process is provided that uses the multi-dimensional library to design the metasurface. For example, an aggregate performance metric of the metasurface may be optimized. In various examples, the distributed optimization strategy of various embodiments is computationally tractable and results in the design of a metasurface with an accurate response.

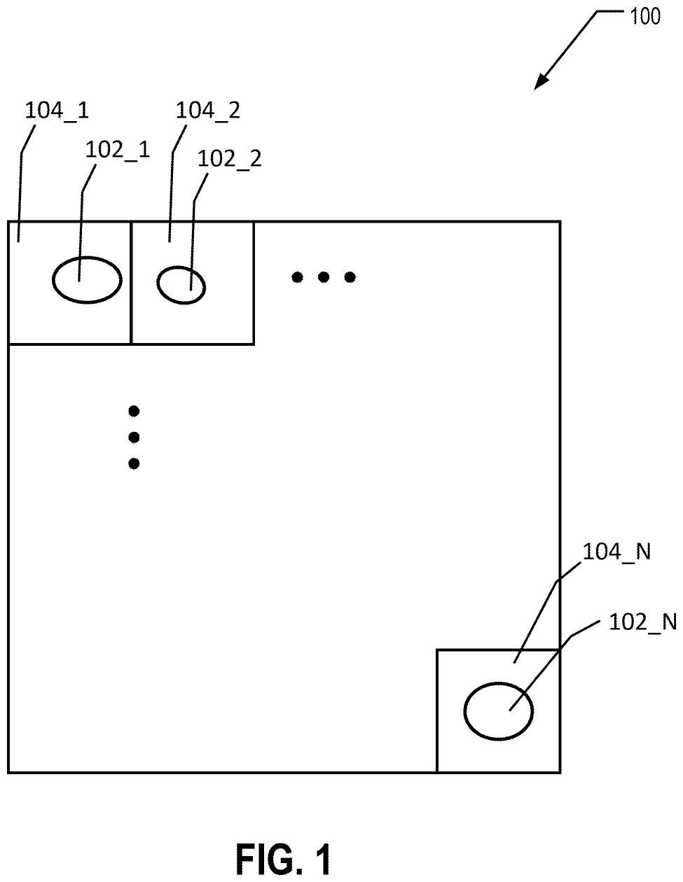

FIG. 1 illustrates a metasurface 100 according to an example embodiment. In various embodiments, the metasurface 100 includes metamaterial structures 102_1, 102_2, . . . , 102_N. Each metamaterial structure 102_1, 102_2, . . . , 102_N may be disposed in a corresponding unit cell 104_1, 104_2, . . . , 104_N of the metasurface 100. In example embodiments, the metasurface 100 may include any number of metamaterial structure(s) and/or unit cell(s). In an example embodiment, a unit cell may not include a metamaterial structure.

In various embodiments, the metasurface 100 provides a manipulation function on an incident signal, such as incident light and/or electromagnetic beam. For example, the metasurface 100 may focus, diverge, collimate, and/or redirect the incident signal in various other forms and shapes.

In example embodiments, for the metasurface 100 to provide the appropriate manipulation function on the incident signal, each metamaterial structure 102_1, 102_2, . . . , 102_N may perform a unique manipulation on the signal. For example, each metamaterial structure 102_1, 102_2, . . . , 102_N may change and/or shift a phase of the incident signal in certain amount(s). In some examples, each metamaterial structure 102_1, 102_2, . . . , 102_N may change and/or shift a frequency and/or amplitude of the incident signal in certain amount(s).

In various embodiments, various properties for each of the metamaterial structures 102_1, 102_2, . . . , 102_N determine how each metamaterial structure manipulates the signal. In example embodiments, metamaterial structures 102_1, 102_2, . . . , 102_N may each be a pillar, column, and/or the like. The various properties of the meta martial structures may for example include the shape, size, geometry, fill factor, orientation, or location of the metamaterial structure (such as the pillar, column, and/or the like) within unit cells 404_1, . . . , 404_N of the metasurface. In the example embodiment of FIG. 1, the shape, orientation, location, size, and fill factor of metamaterial structures 102_1, 102_2, . . . , 102_N may vary from one to another.

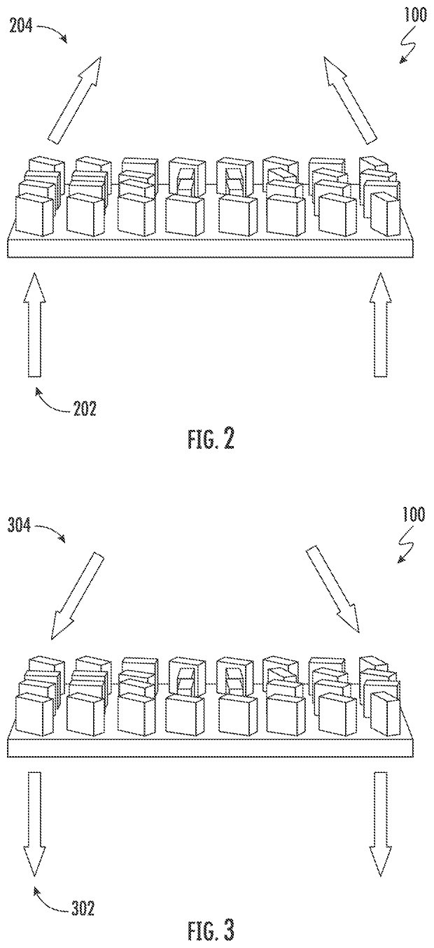

FIG. 2 illustrates an example embodiment for the metasurface 100 configured to manipulate an incident beam 202 into a focused beam 204, according to various embodiments herein. FIG. 3 illustrates an example embodiment for the metasurface 100 configured to manipulate a reciprocal incident beam 304 into a collimated beam 302, according to various embodiments herein. In various examples, signals 202 and 302 are parallel and overlap while having reverse directions with respect to each other. Similarly, in various examples, signals 204 and 304 are parallel and overlap while having reverse directions with respect to each other.

In various embodiment, the metasurface 100 is expected to provide a symmetrical manipulation function to an incident signal and a reciprocal signal, as for example illustrated in FIGS. 2 and 3. Various embodiments herein use the symmetrical requirement for the manipulation function to design the metasurface 100 by determining the property(ies) of each of the metamaterial structures and to provide the required manipulation function, in a distributed manner.

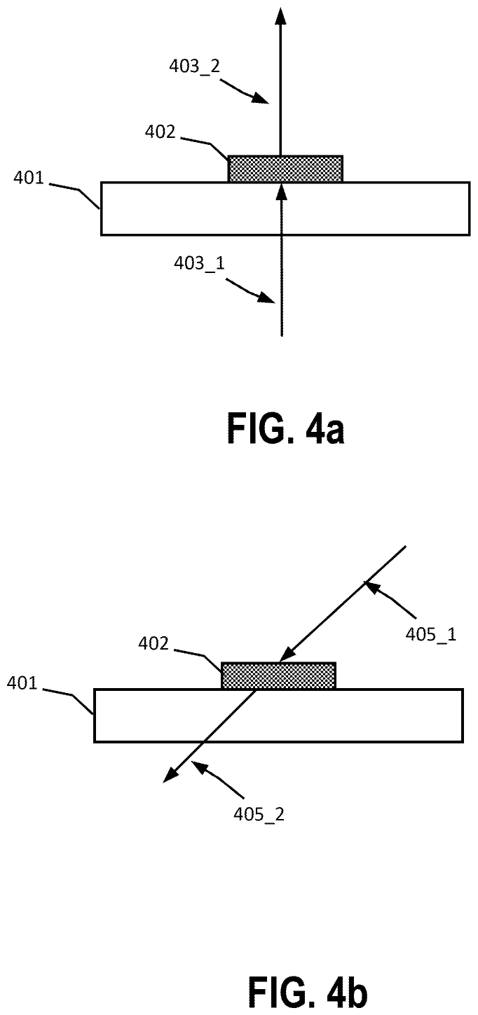

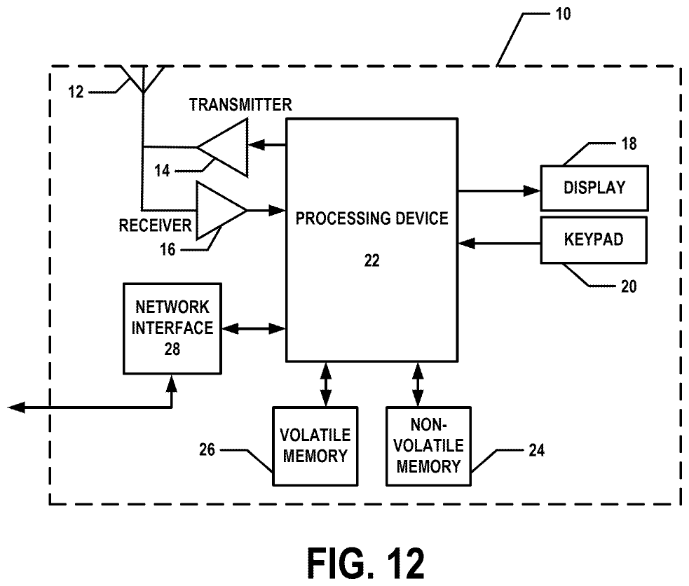

FIGS. 4(a) and 4(b) are schematic diagrams used to illustrate a distributed optimization for designing a metasurface according to various embodiments herein. In various embodiments, a computing entity, such as a computing entity 10 as for example illustrated in FIG. 12 and as further described below, is used to perform various steps of the optimization method.

In various embodiments herein, the computing entity 10 selects a metamaterial structure 402 from the metamaterial structures of a metasurface. In various embodiments, the metamaterial structure 402 is located in a unit cell 401. In various embodiments, the computing entity 10 generates a forward light propagation model for the metamaterial structure 402. For example, the computing entity 10 uses a simulation-based model to model how the metamaterial structure 402 manipulates any of a phase, amplitude and/or polarization of a light beam such as a forward incident light beam 403_1. The metamaterial structure 402 manipulates the forward incident light beam 403_1 into the forward light beam 403_2. In various embodiments, when simulating an individual metamaterial structure such as the metamaterial structure 402 in the distributed optimization, the forward light passes through without a change in angle. For example the angle of the forward incident light beam 403_1 and the forward light beam 403_2 remain the same, as illustrated in FIG. 4a.

In various embodiments, the computing entity 10 generates a reciprocal light propagation model for the metamaterial structure 402 using the light manipulation function. For example, the computing entity 10 generates the reciprocal light propagation model for the reverse incident light beam 405_1 and the reverse light beam 405_2. For example, the computing entity 10 uses a simulation-based model to model how the metamaterial structure 402 manipulates any of a phase, amplitude and/or polarization of a light beam such as the reverse incident light beam 405_1. In various embodiments, when simulating an individual metamaterial structure such as the metamaterial structure 402 in the distributed optimization, the reverse light passes through without a change in angle. For example the angle of the reverse incident light beam 405_1 and the reverse light beam 405_2 remain the same, as illustrated in FIG. 4b. In various embodiments, the incident angle of the reverse incident light beam 405_1 is determined by the light manipulation function for the metasurface and the angle of the incident light beam. For example, the angle of the reverse incident light beam 405_1 is determined using the light manipulation function for the metasurface and the incident angle of the forward incident light beam 403_1. For example, the angle of the reverse incident light beam 405_1 is any angle change the light manipulation function causes on the forward incident light beam 403_1 on the metasurface as a whole. For example, if the light manipulation function is that of a focusing, such as the examples of FIGS. 2 and 3, the reverse incident light beam has the same angle as beam 304 shown in FIG. 3.

In various embodiments, due to the symmetrical requirement of the metasurface, an electromagnetic response for the forward and reciprocal light propagation directions are equal. In various embodiments, the computing entity 10 determines the electromagnetic response difference in the forward light propagation model and the reciprocal light propagation model. In various embodiments, the computing entity 10 determines an optimized property range of the metamaterial structure 402 such that the electromagnetic response difference is optimized. In various embodiments, the electromagnetic response difference is optimized such that an aggregate performance metric of the metasurface is optimized. In various embodiments, the electromagnetic response may be phase delay, amplitude and/or polarization change caused by the metamaterial structure.

For example, the computing entity 10 determines the phase delay difference in the forward light propagation model and the reciprocal light propagation model. In various embodiments, the computing entity 10 determines an optimized property range of the metamaterial structure 402 such that the phase delay difference is optimized. For example, the computing entity 10 determines a shape and/or physical dimension range of the metamaterial structure 402 such that the phase delay difference is optimized. For example, if the metamaterial structure 402 is a cylindrical metamaterial structure, the computing entity 10 determines a diameter range of the metamaterial structure 402 such that the phase delay difference is optimized.

In various embodiments, due to the symmetrical requirement of the metasurface, an amplitude for the forward and reciprocal light propagation directions are equal. In various embodiments, the computing entity 10 determines the amplitude difference in the forward light propagation model and the reciprocal light propagation model. In various embodiments, the computing entity 10 determines an optimized property range of the metamaterial structure 402 such that the amplitude difference is optimized. For example, the computing entity 10 determines a shape and/or physical dimension range of the metamaterial structure 402 such that the amplitude difference is optimized. For example, if the metamaterial structure 402 is a cylindrical metamaterial structure, the computing entity 10 determines a diameter range of the metamaterial structure 402 such that the amplitude difference is optimized.

In various embodiments, due to the symmetrical requirement of the metasurface, a polarization for the forward and reciprocal light propagation directions are equal. In various embodiments, the computing entity 10 determines the polarization difference in the forward light propagation model and the reciprocal light propagation model. In various embodiments, the computing entity 10 determines an optimized property range of the metamaterial structure 402 such that the polarization difference is optimized. For example, the computing entity 10 determines a shape and/or physical dimension range of the metamaterial structure 402 such that the polarization difference is optimized. For example, if the metamaterial structure 402 is a cylindrical metamaterial structure, the computing entity 10 determines a diameter range of the metamaterial structure 402 such that the polarization difference is optimized.

In various embodiments, the light manipulation function of the metasurface is a refractive or reflective light manipulation function. For example, the metasurface may function as a signal focusing and or diverging lens and or reflector. In an example, the metasurface may be any of a spherical, cylindrical, and/or a combination lens and/or reflector.

The metamaterial structures at or close to the periphery of the metasurface may cause the steepest impact on the phase of an incident signal and their optimization may be more prone to error. In various embodiments, when the light manipulation function of the metasurface is a refractive light manipulation function, the metamaterial structures at or close to the periphery of the metasurface may be more important to optimize than the rest of the metamaterial structures because they may benefit the most from the optimization methods as provided herein. In various embodiments, the computing entity 10 selects the metamaterial structure 402 from a periphery of a metasurface. In various embodiments, the computing entity 10 selects the metamaterial structure 402 from a portion of the metasurface that are closer to periphery of a metasurface than for example 75% of other metamaterial structures. In various embodiments, the computing entity 10 selects the metamaterial structure 402 from a portion of the metasurface that are closer to periphery of a metasurface than for example 50% of other metamaterial structures.

In an embodiment the signals 403_1, 403_2, 405_3 and/or 405_2 are simulated signals. In an embodiment herein, a simulation program may be stored in the non-volatile memory 24 of a computing entity 10, as shown in FIG. 12 below, for providing the simulation including the simulated signals.

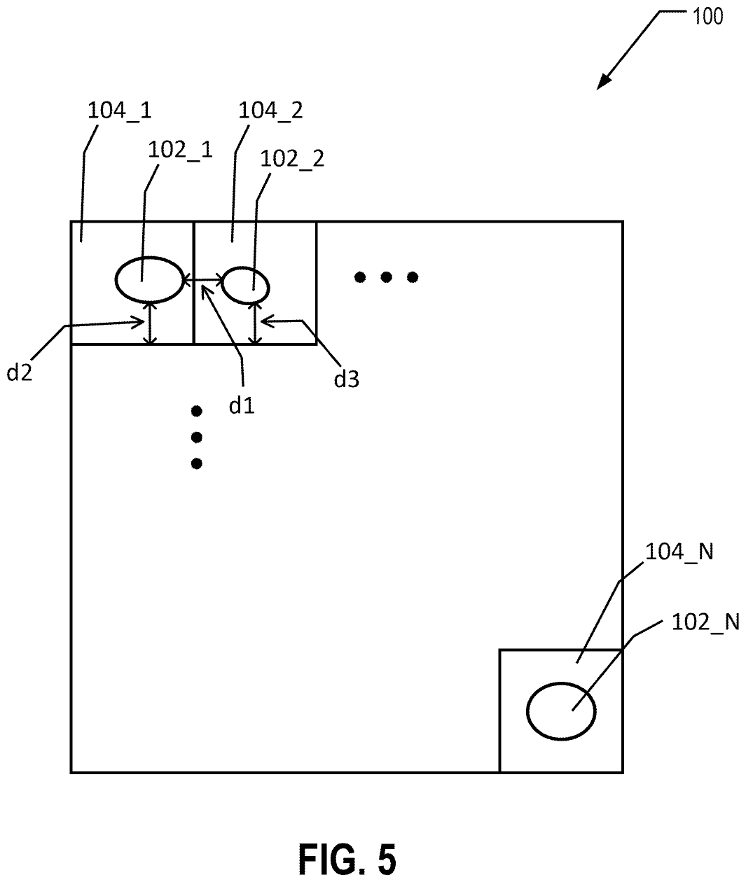

FIG. 5 is a schematic diagram illustrating the metasurface 100 in accordance with various embodiments herein. In various embodiments, the computing entity 10 selects the metamaterial structure 102_1 as the metamaterial structure 420 to perform the simulation functions for optimizing the metasurface 100 described above with respect to FIGS. 4a and 4b. In various embodiments, the computing entity 10 determines an optimized property range for the first metamaterial structure 102_1 such that any of the phase delay difference, amplitude difference, and/or polarization difference is optimized in the forward and reciprocal light propagation models.

In various embodiments, the computing entity 10 selects a second metamaterial structure 102_2 of a plurality of metamaterial structures of the metasurface 100. In various embodiment, the computing entity 10 generates the forward light propagation model and the reciprocal light propagation model using the light manipulation function for the second metamaterial structure 102_2 also as for example described above with respect to FIGS. 4a and 4b.

In various embodiments, the computing entity 10 determines a phase delay difference in the forward light propagation model and the reciprocal light propagation model for the metamaterial structure 102_2. In various embodiments, the computing entity 10 determines an optimized property range for the second metamaterial structure 102_2 such that the phase delay difference is optimized. For example, the computing entity 10 determines a shape and/or physical dimension range of the metamaterial structure 102_2 such that the phase delay difference is optimized. In various embodiments, the computing entity 10 may determine an optimized property range such that any of an amplitude and or polarization difference in the forward light propagation model and the reciprocal light propagation model for the metamaterial structure 102_2 is optimized.

In various embodiments herein, the computing entity 10 determines a first property value within the first property range for the metamaterial structure 102_1. For example, the computing entity 10 determines a diameter for the metamaterial structure 102_1. In various embodiments, the computing entity 10 determines a first location for the metamaterial structure 104_1 on the unit cell 104_1 of the metasurface 100.

In various embodiments herein, the computing entity 10 determines a second property value within the second property range for the metamaterial structure 102_2. For example, the computing entity 10 determines a diameter for the metamaterial structure 102_2. In various embodiments herein, the computing entity 10 determines a second location for the metamaterial structure 102_2 on a second unit cell 104_2 adjacent to the first unit cell 104_1.

In various embodiments wherein the first and second property values and locations for the metamaterial structures 102_1 and 102_2 are determined to meet geometrical constraints of the metasurface. For example, the geometrical constrains may be a minimum and/or maximum distance requirement of each of the metamaterial structures from a periphery of unit cells and/or from each other. For example, the geometrical constraints for the metamaterial structures 102_1 and 102_2 may be constraints on a distance d1 between the two metamaterial structures 102_1 and 102_2 and/or constraints on the distances d2 and d3 from the edges of the unit cells 104_1 and 104_2. For example, each of the distances, e.g. d1, d2, d3 may be constrained to a minimum and/or a maximum.

In various embodiments, the geometrical constraint may include constraints on a fill fraction of each metasurface structure in its corresponding unit cell. For example, the geometrical constraint may include a minimum and/or a maximum of a ratio of a two-dimensional surface area of a cross section of metasurface structures 102_1 or 102_2 to the corresponding unit cell 104_1 or 104_2. The cross section of the metasurface structures may be at a plane parallel to or on the surface of the corresponding unit cells.

In various embodiments, when the placing of the metamaterial structure, for example metamaterial structure 102_2 in the unit cell 104_2 is adjusted during the optimization process, it may impact and/or change the phase delay caused by the metamaterial structure 102_2. To optimize the phase delay, the second property value of the metamaterial structure 102_2 (e.g. its diameter) may need to be updated. Therefore, various embodiments provide a co-optimization of determining and/or updating the property values for the metamaterial structures when the placing of the metamaterial structures in the unit cells are determined.

In various embodiments, the geometrical constraints are used to account for a local coupling between the metamaterial structures on a metasurface. For example, by limiting a distance between the two metasurface structures 102_1 and 102_2 a local coupling between the two metasurface structures may be limited. In various embodiments, by limiting a distance between the two metasurface structures 102_1 and 102_2 a local coupling between the two metasurface structures is minimized. In various embodiments, by limiting a distance between the two metasurface structures 102_1 and 102_2 and/or any geometrical constraints, local coupling between neighboring metamaterial structurers, such as metasurface structures 102_1 and 102_2, is kept consistent.

In various embodiments herein, the optimization process continues to a last metamaterial structure, for example metamaterial structure 102_N in the unit cell 104_N, and performs the steps described above taking into account all other meta material structures previously placed.

In various embodiments, when after the metasurface is designed using any of the distributed modeling and/or co-optimization described above, the placement of metamaterial structurers may no longer form a geometrical pattern, such as a geometrical lattice, based on the unit cell arrangements. Various embodiments, may use a fill fraction of a local region and/or a local density of the metamaterial structures for finalizing the metasurface design. For example, various embodiments may finalize designing and/or optimizing the metasurface with an optimization process using geometrical constraints based on a fill fraction of a local region of the metamaterial structures coupling between adjacent metamaterial structures are consistent. In example embodiments, the local region may include two neighboring metamaterial structures. In example embodiments, the local region may include three neighboring metamaterial structures. In example embodiments, the local region may include four neighboring metamaterial structures. In example embodiments, the local region may include five or more neighboring metamaterial structures.

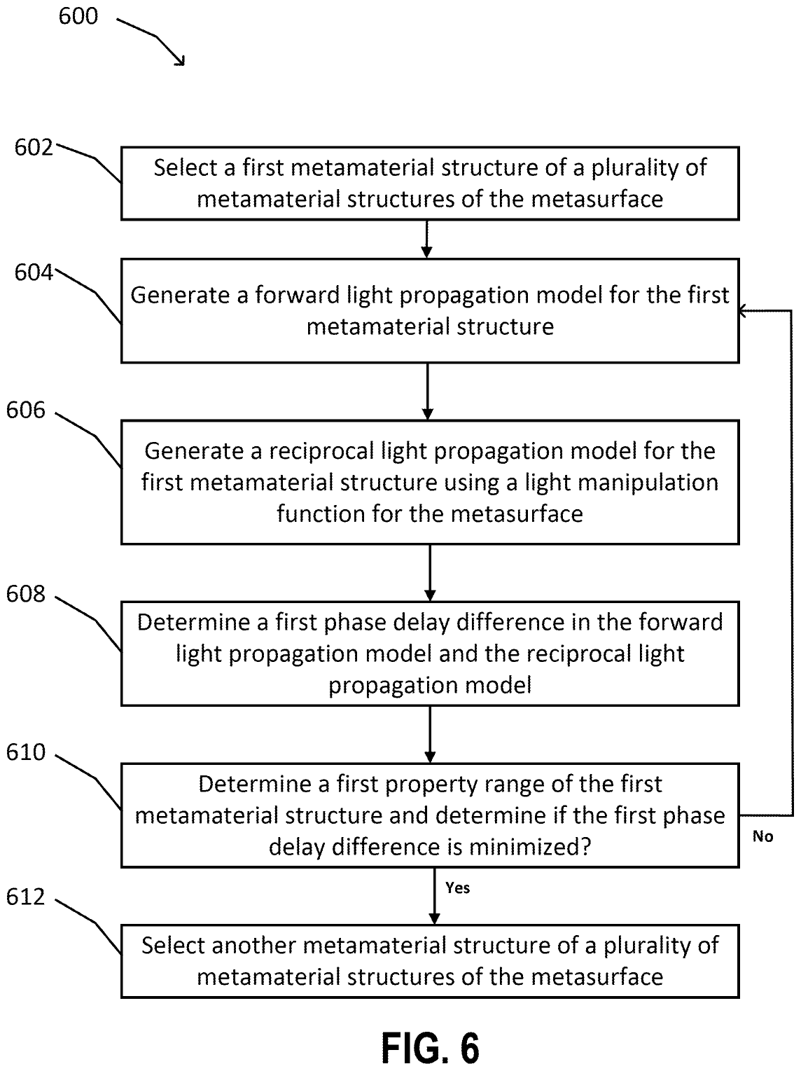

FIG. 6 is a flowchart illustrating a method 600 according to various embodiments herein. In accordance with various embodiments herein, a computing entity 10 comprises means, such as processing device 22, memory 26, 24, and/or the like as for example illustrated in FIG. 12 herein, is used for initiating a metasurface optimization and/or various other steps of the method 600.

In various embodiments, at step 602, the computing entity 10 selects a first metamaterial structure of a plurality of metamaterial structures of a metasurface. For example, the computing entity 10 selects the metamaterial structure 102_1 of the metasurface 100, referring to FIG. 1 and/or FIG. 5. In an example embodiment, the selecting the first metamaterial structure comprises selecting a height, shape, width, length, radius/diameter, location of the metamaterial structure within the corresponding unit cell. In various embodiments, the first metamaterial structure is selected based on a default initial metamaterial structure, user input (e.g., received via a user input device of the computing entity 10), an intended function of the metasurface, and/or the like.

In various embodiments, at step 604, the computing entity 10 generates a forward light propagation model for the first metamaterial structure. For example, the computing entity 10 generates the forward light propagation model as illustrated and described with respect to FIG. 4a. The forward light propagation model may be based on the light manipulation function for the metasurface describing the intended function the metasurface performs on an incident light. For example, the light manipulation function may be any of a focusing function, diverging function, collimating function, and/or any other beamforming function(s). For example, the computing entity 10 simulates the response of a forward incident light beam 403_1 interacting with the first metamaterial structure to induce a forward light beam 403_2. In an example embodiment, determining the forward light propagation model for the first metamaterial structure comprises determining one or more characteristics of the forward light beam 403_2 (e.g., phase delay, polarization, amplitude, frequency, and/or the like).

In various embodiments, at step 606, the computing entity 10 generates a reciprocal light propagation model for the first metamaterial structure using the light manipulation function for the metasurface. For example, the computing entity 10 simulates the reciprocal light propagation model illustrated and described with respect to FIG. 4b on the selected first metamaterial structure. In various examples, the reciprocal light propagation model includes beam of light incident with an angle determined based on the light manipulation function of the metasurface. For example, the computing entity 10 simulates the response of a reverse incident light beam 405_1 interacting with the first metamaterial structure to induce a reverse light beam 405_2. In an example embodiment, determining the reverse light propagation model for the first metamaterial structure comprises determining one or more characteristics of the reverse light beam 405_2 (e.g., phase delay, polarization, amplitude, frequency, and/or the like).

In various embodiments, at step 608, the computing entity 10 determines a first phase delay difference in the forward light propagation model and the reciprocal light propagation model. For example, the computing entity 10 determines a difference in phase delay caused on the forward light propagation model (e.g. referring to FIG. 4a) and the phase delay caused on the reverse light propagation model (e.g., referring to FIG. 4b) as applied to the first metamaterial structure. For example, the computing entity 10 determines a forward phase delay or change in phase between the forward incident light beam 403_1 and the forward light beam 403_2 caused by the interaction of the forward incident light beam 403_1 with the first metamaterial structure. The computing entity 10 also determines a reverse phase delay or change in phase between the reverse incident light beam 405_1 and the reverse light beam 405_2 caused by interaction of the reverse incident light beam 405_1 with the first metamaterial structure. The computing entity 10 determines the first phase delay difference by determining the difference between the forward phase delay and the reverse phase delay.

In various embodiments, at step 610, the computing entity 10 determines a first property range of the first metamaterial structure such that the first phase delay difference is optimized. For example, the first property of the first metamaterial structure may be a diameter of the first metamaterial structure. In an example embodiment, the computing entity 10 runs an optimization framework for determining the diameter (or a range for the diameter) of the first metamaterial structure while optimizing the first phase delay difference. In various examples, the first property of the first metamaterial structure may be other parameters such as shape (e.g., shape of a cross-section of the first metamaterial structure taken in a plane that is perpendicular to a normal to a surface on which the first metamaterial structure is being modeled as being formed on), circumference, refractive index, or other physical parameters and/or dimensions of the first metamaterial structure.

In various embodiments at step 610, the computing entity 10 determines whether the first property range of the first metamaterial structure may in fact optimize the first phase delay difference. If at step 610, the first property range of the first metamaterial structure does not optimize the first phase delay difference, the method 600 repeats steps 604 to 608 by updating the first property and/or property range of the first metamaterial structure as described above.

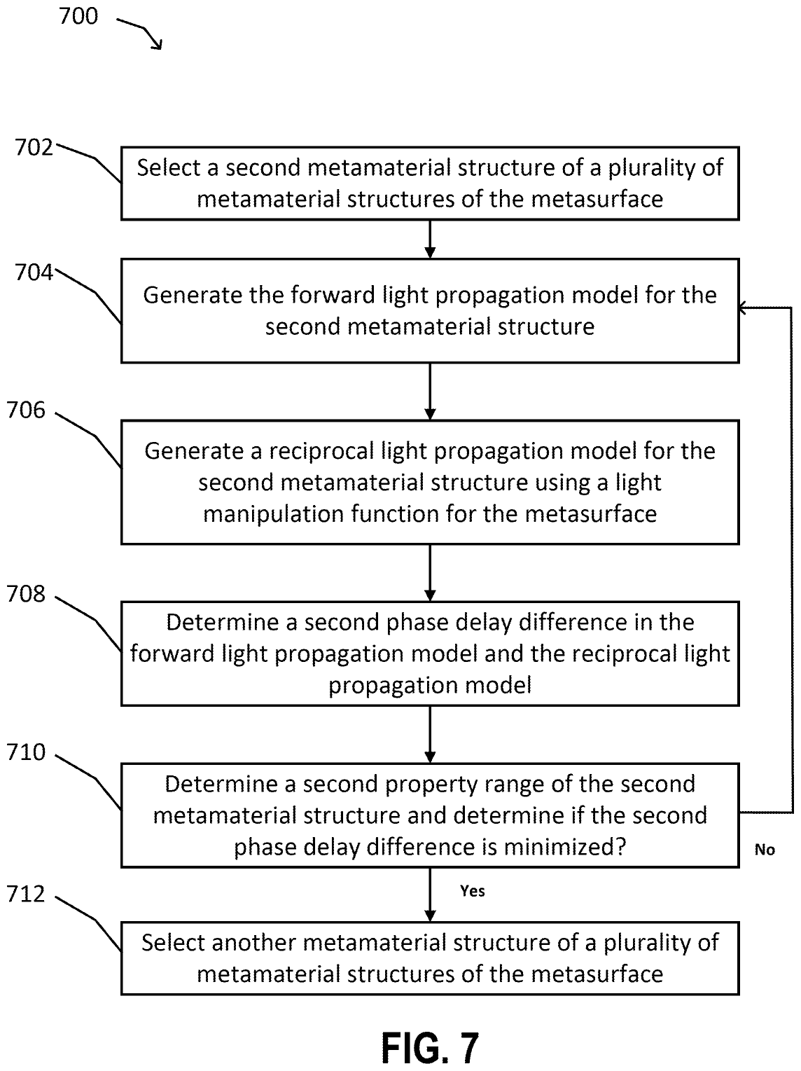

In various embodiments, if at step 610, the first property range of the first metamaterial structure optimizes the first phase delay difference, the computing entity 10, at step 612 selects another metamaterial structure of the plurality of metamaterial structures of the metasurface and repeats the optimization process for the other metamaterial structure, for example as described below with reference to FIG. 7.

FIG. 7 is a flowchart illustrating a method 700 according to various embodiments herein. In various embodiments, at step 702, the computing entity 10 selects a second metamaterial structure of a plurality of metamaterial structures of the metasurface. For example, the computing entity 10 selects the metamaterial structure 102_2 referring to FIG. 1 and/or FIG. 5. In an example embodiment, the selecting the second metamaterial structure comprises selecting a height, shape (e.g., shape of a cross-section of the second metamaterial structure taken in a plane that is perpendicular to a normal to a surface on which the first metamaterial structure is being modeled as being formed on), width, length, radius/diameter, location of the second metamaterial structure within the corresponding unit cell. In various embodiments, the second metamaterial structure is selected based on a default initial metamaterial structure, user input (e.g., received via a user input device of the computing entity 10), an intended function of the metasurface, and/or the like.

In various examples, at step 704, the computing entity 10 generates the forward light propagation model for the second metamaterial structure. For example, the computing entity 10 generates the forward light propagation model as illustrated and described with respect to FIG. 4a. The forward light propagation model may be based on the light manipulation function for the metasurface describing the intended function the metasurface performs on the incident light. For example, the computing entity 10 simulates the response of a forward incident light beam 403_1 interacting with the second metamaterial structure to induce a forward light beam 403_2. In an example embodiment, determining the forward light propagation model for the second metamaterial structure comprises determining one or more characteristics of the forward light beam 403_2 (e.g., phase delay, polarization, amplitude, frequency, and/or the like).

In various embodiments, at step 706, the computing entity 10 generates a reciprocal light propagation model for the second metamaterial structure using the light manipulation function for the metasurface. For example, the computing entity 10 simulates the reciprocal light propagation model illustrated and described with respect to FIG. 4b on the selected second metamaterial structure. In various examples, the reciprocal light propagation model includes beam of light incident with an angle determined based on the light manipulation function of the metasurface. For example, the computing entity 10 simulates the response of a reverse incident light beam 405_1 interacting with the second metamaterial structure to induce a reverse light beam 405_2. In an example embodiment, determining the reverse light propagation model for the second metamaterial structure comprises determining one or more characteristics of the reverse light beam 405_2 (e.g., phase delay, polarization, amplitude, frequency, and/or the like).

In various embodiments, at step 708, the computing entity 10 determines a second phase delay difference in the forward light propagation model and the reciprocal light propagation model. For example, the computing entity 10 determines a difference in phase delay caused on the forward light propagation model (e.g. referring to FIG. 4a) and the phase delay caused on the reverse light propagation model (e.g., referring to FIG. 4b) as applied to the second metamaterial structure. For example, the computing entity 10 determines a forward phase delay or change in phase between the forward incident light beam 403_1 and the forward light beam 403_2 caused by the interaction of the forward incident light beam 403_1 with the second metamaterial structure. The computing entity 10 also determines a reverse phase delay or change in phase between the reverse incident light beam 405_1 and the reverse light beam 405_2 caused by interaction of the reverse incident light beam 405_1 with the second metamaterial structure. The computing entity 10 determines the second phase delay difference by determining the difference between the forward phase delay and the reverse phase delay.

In various embodiments, at step 710, the computing entity 10 determines a second property range of the second metamaterial structure such that the second phase delay difference is optimized. For example, the second property of the second metamaterial structure may be a diameter of the second metamaterial structure. In an example embodiment, the computing entity 10 runs an optimization framework for determining the diameter (or a rage for the diameter) of the second metamaterial structure while optimizing the second phase delay difference. In various examples, the second property of the second metamaterial structure may be other parameters such as shape (e.g., shape of a cross-section of the first metamaterial structure taken in a plane that is perpendicular to a normal to a surface on which the first metamaterial structure is being modeled as being formed on), circumference, refractive index, or other physical parameters and/or dimensions of the second metamaterial structure.

It is noted that in various embodiments, instead of the first or second phase delay difference, a first or second amplitude and/or polarization difference between the forward and reverse propagation models may be calculated. The optimization model may then determine the first and/or second properties for the first and/or second metamaterial structures while optimizing the amplitude and/or polarization difference.

In various embodiments at step 710, the computing entity 10 determines whether the second property range of the second metamaterial structure may in fact optimize the second phase delay difference. If at step 710, the second property range of the second metamaterial structure does not optimize the second phase delay difference, the method 700 repeats steps 704 to 708 by updating the second property and/or property range of the second metamaterial structure as described above.

In various embodiments, if at step 710, the second property range of the second metamaterial structure optimizes the second phase delay difference, the computing entity 10, at step 712 selects another metamaterial structure of the plurality of metamaterial structures of the metasurface and repeats the optimization process for the other metamaterial structure, until the last metamaterial structure is selected and its property ranges are determined and optimized such that they optimize the corresponding phase delay difference.

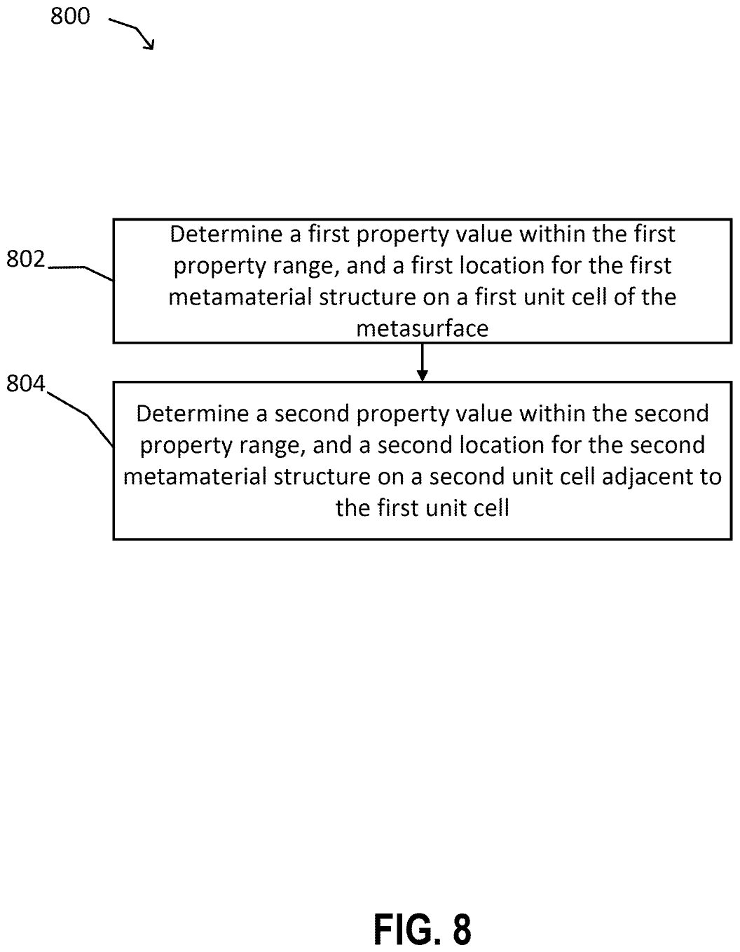

FIG. 8 is a flowchart illustrating a method 800 according to various embodiments herein. In various embodiments, at step 802, the computing entity 10 determines a first property value within the first property range for the first metasurface structure. In various embodiments, the computing entity 10 may determine a first location for the first metamaterial structure on a first unit cell of the metasurface. For example, the computing entity 10 determines one or more properties of the first metamaterial structure (e.g. a metamaterial structure, 104_1 referring to FIG. 5) in a unit cell corresponding to the first metamaterial structure (e.g. corresponding unit cell 104_1 referring to FIG. 5) of the metasurface. In various embodiments determining one or more properties of the metamaterial structure may include determining any of a shape, size, circumference, refractive index, geometry, fill factor, orientation, and/or location of the metamaterial structure (such as a pillar) within a corresponding unit cell.

In various embodiments, at step 804, the computing entity 10 determines a second property value within the second property range, and a second location for the second metamaterial structure (e.g. a metamaterial structure, 104_2 referring to FIG. 5) on a second unit cell adjacent to the first unit cell (e.g. corresponding unit cell 104_2 referring to FIG. 5). In various embodiments, the computing entity 10 determines the second property value and location such that the geometrical constrains for the metasurface, as for example described with respect to FIG. 5, are satisfied. For example, the second property of the second metamaterial structure is determined such that a minimum distance requirement for the first and second metamaterial structures from an edge of the corresponding first and second unit cells are met.

In various embodiments, when optimizing properties of a metasurface for a specific phase mask of the metasurface, a target phase delay provided by a forward response of a metamaterial structure does not need to be the same as of the reciprocal response. This may be due to a relative nature of the phase. Therefore for a given phase curvature or phase mask of the metasurface, the forward phase response of each metamaterial structure of the metasurface may be offset from the reciprocal phase response with a fixed phase value.

Therefore, in various embodiments, the relative phase response of the metamaterial structures in each direction is the design target. Therefore, in various embodiments, the forward and reciprocal phase delays do not need to equal each other and may be offset from each other.

In various embodiments, an optimization process begins with a phase curvature required for the metasurface. The phase curvature may be based on the light manipulation function that is required of the metasurface, for example a focusing or collimating function for a lens, etc. By discretizing the phase curvature for each unit cell, a phase mask may be produced. In various embodiments, the phase mask may provide the relative phase response requirement of each metamaterial structure with respect to its neighboring metamaterial structures. In various embodiments, the phase mask for forward and reciprocal directions may be shifted from each other with a fixed value.

In various embodiments, the optimization process may select one metamaterial structure, optimize the properties of the metamaterial structure to achieve an optimum phase response in the forward and reciprocal directions. The phase delay response in each forward and reciprocal directions may then serve as a reference phase value in the rest of the optimization process in each direction. However, the physical properties of the metamaterial structure are the same regardless of the direction at which it is used. For example, a diameter value of a cylindrical metamaterial structure is the same regardless of the direction in which the metamaterial structure is used.

In various embodiments, a reference metamaterial structure is selected such that the forward and reciprocal phase delays of the metamaterial structure is the same or minimized. In the example of a focusing/collimating lens, a metamaterial structure at the venter of the metasurface may have the same forward and reciprocal phase delays.

After selecting the metamaterial structure for which the forward phase and the reverse phase difference is approximately zero or is minimum, the forward phase delay provided by the reference metamaterial structure may be used as a reference for the optimization process to create the phase curvature or phase mask of the rest of the metasurface in the forward direction and the reciprocal phase delay may be used as a reference for the optimization process to create the phase curvature or phase mask of the metasurface in the reciprocal direction. However, as previously mentioned, all the forward and reciprocal phase delays may be offset from each other by a fixed value.

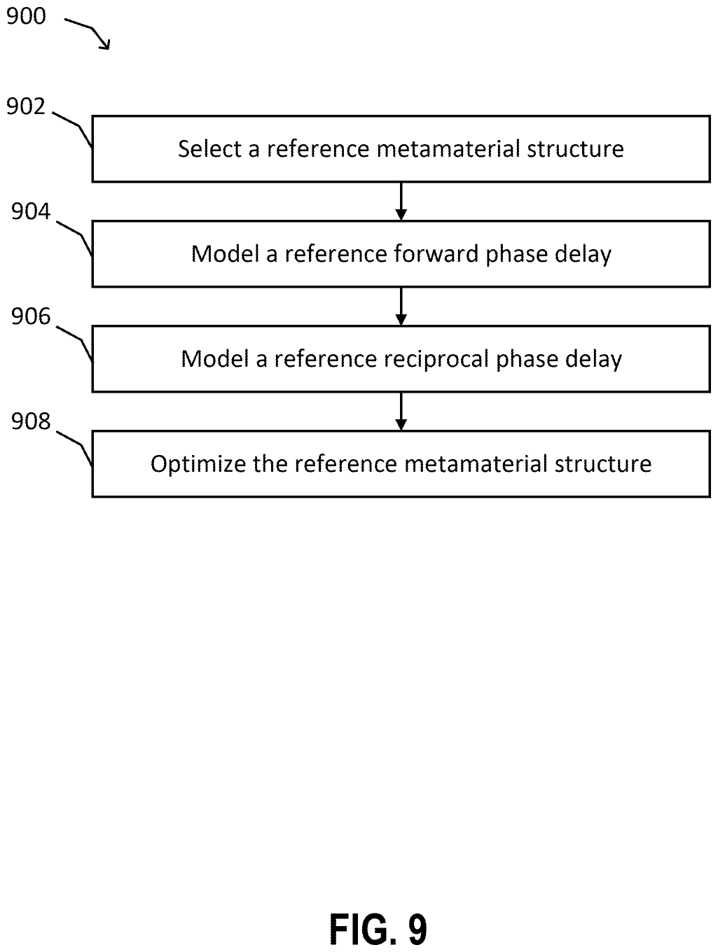

FIG. 9 is a flowchart illustrating a method 900 for designing a metasurface according to various embodiments herein. In various embodiments, at step 902, the computing entity 10 selects a reference metamaterial structure from the metamaterial structures of the metasurface.

In various embodiments, at step 904, the computing entity 10 models a reference forward phase delay. The computing entity 10 may determine a reference forward phase delay versus a property of the reference metamaterial structure for a forward incident angle. For example, when the metamaterial structures are cylindrical, the computing entity 10 may provide a model representing forward phase delays provided by the refence metamaterial structure versus a diameter of the metamaterial structure.

In various embodiments, at step 906, the computing entity 10 models a reference reciprocal phase delay. The computing entity 10 may determine a reference reciprocal phase delay versus the property of the reference metamaterial structure for a reverse incident angle versus a property of the reference metamaterial structure for a reverse incident angle. For example, when the metamaterial structures are cylindrical, the computing entity 10 may provide a model representing reverse phase delays provided by the refence metamaterial structure versus a diameter of the metamaterial structure.

In various embodiments, at step 908, the computing entity 10 optimizes the reference metamaterial structure. The computing entity 10 may determine the property of the reference metamaterial structure such that a difference between the forward phase delay and the reciprocal phase delay is optimized.

In various embodiments, the computing entity 10 optimizes an aggregate performance metric of the metasurface to optimize the forward and/or reciprocal phase delay for a metamaterial structure. For example, the computing entity 10 may maximize an aggregate performance metric of the metasurface to optimize the forward and/or reciprocal phase delay for a metamaterial structure. For example, the computing entity 10 may minimize an aggregate performance metric of the metasurface to optimize the forward and/or reciprocal phase delay for a metamaterial structure.

In example embodiments, the computing entity 10 selects the reference metamaterial such that a difference between the forward incident angle and the reciprocal incident angle is minimized.

In various embodiments, the forward phase delay and the reciprocal phase delay may be offset with a fixed phase value. This may be because the relative phase delays in the forward and reciprocal directions determine the light manipulation function of the metasurface. Therefore, the optimized forward phase delay and the optimized reciprocal phase delay may be offset with a fixed phase value while the metasurface is optimized.

In various embodiments, the computing entity 10 determines the forward incident angle and the reverse incident angle using a phase mask of the metasurface. The computing entity 10 may determine the phase mask of the metasurface using a light manipulation function for the metasurface. In various embodiments, the computing entity 10 determines a phase curvature of the metasurface, and discretizes the phase curvature at every unit cell to determine the phase mask which includes discrete phase values corresponding to each unit cell.

In various embodiments, the computing entity 10 determines the properties of another metamaterial structure by referencing a forward phase delay of the other metamaterial structure with the reference forward phase delay and refencing the reverse phase delay of the other metamaterial structure with the reference reverse phase delay. The computing entity 10 may iteratively repeat the determining properties of other metamaterial structures until the metasurface is optimized.

In various embodiments, one or more design libraries are generated that map any of phase delay, amplitude variation, and/or polarization shift of a metamaterial structure to one or more properties of the metamaterial structure. Various embodiments increase the speed of distributed optimization procedures by performing all or some of the modeling and creating the libraries in advance of the optimization procedure.

In various embodiments, the modeling and optimization process may be performed together (for example in parallel or by interleaved various modeling and optimization steps) while designing a metasurface. The generated libraries using the modeling may be stored in a storage system (e.g. a memory) and may be used in a later optimization for a new metasurface.

In various embodiments, a master library may be generated and maintained that may be used in optimizing new metasurfaces. Therefore, the master library may be precomputed before a new optimization process. In various embodiments, the optimization process may select metamaterial structures and/or various properties of a specific type of metamaterial structured from the master library while accounting for the forward and reciprocal angles during the optimization process.

In various embodiments, the parameters for the metamaterial structures may include global parameters, placement parameters and shape parameters.

In various embodiments, the global parameters include height, either unit cell or local area fill fraction, and wavelength. In various embodiments, global parameters are held constant during the optimization process and/or are equal for all elements in the metasurface.

In various embodiments, the shape parameters of a metamaterial structure determine a shape of the metamaterial structure. For example, for a cylindrical structure the shape parameter is the diameter of the metamaterial structure (while its height remains constant in various embodiments). For example, for an elliptical metamaterial structure, the shape parameters are the two diameters and a rotation angle of the elliptical cross section. In various embodiments, the shape parameters indicate the shape of the two-dimensional cross section of the metamaterial structure.

In various embodiments, the placement parameters of a metamaterial structure determine the forward and/or reciprocal incident angles, including the elevation and azimuth angles. The elevation angle may determine the deviation from normal, and the azimuth angle may determine the rotation around the normal axis. Therefore, the placement parameters include the k-vector of the incident light (in the forward and/or reciprocal directions). In various embodiments, the placement parameters also include the polarization shift provided by a metamaterial structure in the forward and/or reciprocal directions.

In various embodiments, when compiling the master library, the photonic response to various possible situations is evaluated and recorded. In various embodiments, the photonic response of a metamaterial structure in response to various placement and shape parameters are evaluated and recorded. For example, the phase delay and or amplitude variation in response to various placement and/or shape parameters may be evaluated and recorded.

For example, a metamaterial structure on the metasurface may be selected. The metamaterial structure may have fixed global parameters (e.g., its height and its spacing are fixed). In various embodiments, by knowing the light manipulation function of the metasurface (which may indicate how the metasurface is expected to manipulate light), the placement parameters are determined. For example, in a focusing/collimating metasurface, by knowing the focal point of the metasurface, the placement parameters for various metamaterial structures in various locations on the metasurface are known. However, the metamaterial structure may have any shape. Therefore, various embodiments model all the possible shapes to build the master library.

Therefore, in various embodiments, to have a complete master library that can be used for any arbitrary design, a photonic response (e.g., phase delay) is determined and recorded in the library for various combination of possible values for incident elevation and azimuth angles and polarization shift in the forward and reciprocal directions, and metamaterial structure shapes. Therefore, in various embodiments, the master library is a multi-dimensional library.

In various examples, after a master library is designed, the computing entity 10 may use the light manipulation function of the metasurface to determine a maximum range for the incident angles (in the forward and reciprocal directions) and the polarization requirement for each metamaterial structure. The computing entity 10 may then determine the phase delay for each of such possibilities and then at each of such possibilities for all the shape parameters to build various entries in the master model.

In various embodiments, the computing entity 10 may use various machine learning methods in building the library. For example, the computing entity may determine optical response for certain placement and/or shape parameters and use interpolation to determine the optical response for the in between placement or shape parameters. For example, the computing entity may determine the phase delay for the incident light elevation angles with 1° of granularity and use machine learning to determine the phase delay for incident light elevation angles with 0.1° of granularity. In example embodiments, doing so may speed up the creation of the master library.

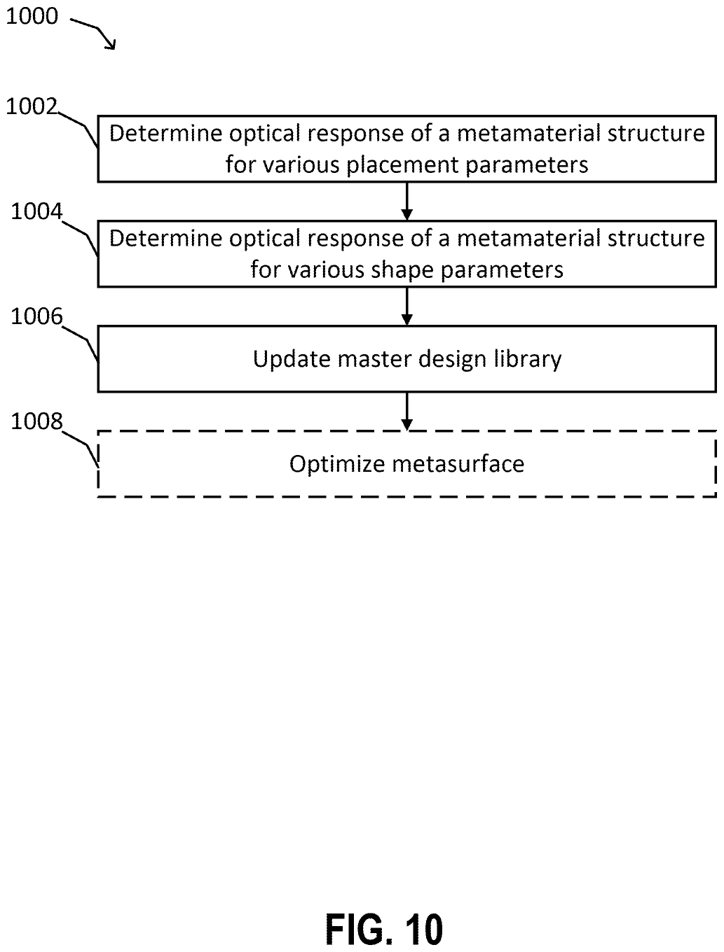

FIG. 10 is a flowchart illustrating a method 1000 for designing a metasurface according to various embodiments herein. In various embodiments, at step 1002, the computing entity 10 determines optical response of a metamaterial structure for various placement parameters. The computing entity 10 may determine an optical response of a metamaterial structure of the metasurface for each value of the values for one or more placement parameters of the metamaterial structure, while keeping one or more global parameters of the metamaterial structure constant. In various embodiments, the optical response may include phase delay, polarization, and/or amplitude variation.

In various embodiments, at step 1004, the computing entity 10 determines optical response of a metamaterial structure for various shape parameters. The computing entity 10 may determine, for each of the values of the one or more placement parameters, the optical response of the metamaterial structure for each value of the values for one or more shape parameters of the metamaterial structure, while keeping the one or more global parameters of the metamaterial structure constant. For example, for each selected and evaluated incident angle and/or polarization parameter, the computing entity determines the optical response for one or more shape parameters.

In various embodiments, at step 1006, the computing entity 10 updates a master design library. The computing entity 10 may record the optical response with respect to each of the values of the one or more placement parameters and each of the one or more shape parameters. For example, the computing entity 10 may create a look up table or a database mapping a phase delay of a metamaterial structure to some or all the possible values of the placement parameters and the shape parameters. The computing entity 10 may create the mapping at two steps, first with respect to the placement parameters then, for each placement parameter value, with respect to the shape parameter values (or vice versa). The computing entity 10 may do so while keeping the global parameters constant for all the metamaterial structures of the metasurface.

In various embodiments, the global parameters include height, local fill fraction, and/or wavelength associated with each metamaterial structure. In various embodiments, the placement parameters include a forward incident angle of a forward optical beam on the metamaterial structure of the metasurface, a reciprocal incident angle of a reciprocal optical beam on the metamaterial structure of the metasurface, a forward polarization of the forward optical beam on the metamaterial structure of the metasurface, and/or a reciprocal polarization of the reciprocal optical beam on the metamaterial structure of the metasurface.

In various embodiments, the forward and/or reciprocal incident angle of the optical beam is determined using the optical manipulation function of the metasurface. In various embodiments, the forward and/or reciprocal polarization is determined using the optical manipulation function of the metasurface.

In various embodiments, if the forward and reciprocal polarizations are not the same, then the metasurface would have locally imparted a polarization shift. But the forward and reciprocal beams themselves are defined independently.

In various embodiments, at step 1008, the computing entity 10 optimizes the metasurface using the master design library. In various embodiments, the computing entity 10 optimizes the metasurface in the forward and reciprocal directions using the master library by determining optimum values of the one or more placement parameters and optimum values of the one or more shape parameters that optimize an aggregate metric for the metasurface.

Various embodiments of the present disclosure use adjoint optimization to optimize the metasurface. In some examples, using adjoint optimization may further optimize the metasurface that may be optimized using another method.

In various embodiments, a design library, such as the master library as previously described, may be used in the adjoint optimization. In various embodiments, the adjoint optimization may uses a design library that does not account for the placement parameters.

In various embodiments, an aggregate optimization process is provided. For example, adjoint optimization may be used to optimize the metasurface for both forward and reciprocal incident beams. The adjoint optimization may be used simultaneously for the forward and reciprocal directions.

An adjoint optimization method may compare a field produced by a metasurface test iteration acting on a pre-defined incident field, with a pre-defined field representing the target of the optimization. Comparison of those fields may yield a response gradient calculated for every metamaterial structure of the metasurface, which may then be used to update the metamaterial structure array for a subsequent iteration.

Adjoint methods may be much more computationally efficient than direct search or gradient descent methods which may require N+1 calculations per iteration where N is the number of parameters being optimized. The adjoint optimization method, however, may run a single test point, M(P) where the metasurface response M is a function of all possible parameters (denoted by vector P) considered by the optimizer. From that one response, the adjoint optimization method may calculate a gradient for each parameter in P. However, the direct search or gradient descent methods run a series of test points (e.g. N+1) to visualize an N-dimensional surface of responses, and then use that to calculate the gradient for each parameter. Those approaches may work well for problems with a small number of parameters.

Metasurfaces, however, may have very large number of parameters (e.g. any shape parameters, multiplied by each element in the array), so using direct search or gradient descent methods may not be computationally feasible. However, the adjoint optimization method makes optimization over large parameter spaces possible.

When using adjoint optimization, the design of the metasurface may be initially unknown but for a known incident field the expected target field is known. In various embodiments, either the electrical and/or magnetic fields of the incident or expected target fields may be used for any of simulations, comparisons, calculations, and/or in various other steps.

In various embodiments, the field of each incident beam in the forward direction is multiplied with the electromagnetic response of a corresponding metamaterial structure to calculate the transformed field by the metasurface. The transformed field may then be compared with the target field. Using the comparison, a gradient for each metamaterial structure is determined. A metamaterial structure gradient indicates a change in one or more parameters of the metamaterial structure needed to for the transformed field to be closer to the target field. In various embodiments, the metamaterial structure gradient indicates a change in one or more shape parameters of the metamaterial structure needed for the transformed field to be approximately the same as the target field. The parameters of the metamaterial structures are then iteratively changed based on the gradient of the metamaterial structure and the transformed field is recalculated until the transformed field is approximately equal the target field and/or when the metasurface is optimized. In various embodiments, the aggregate performance metric used for optimizing the metasurface is for the transformed field to be approximately equal to the target field. For example, a difference between the transformed field and the target field may be minimized.

In various embodiments, the aggregate optimization process is performed accounting for both the forward and reciprocal beams and using the master library as previously described.

In various embodiments, a first adjoint optimization process is performed in the forward direction, using a library accounting for known placement parameters of incident light in the forward direction. A second adjoint optimization process may be performed in the reciprocal direction, using a library accounting for placement parameters of incident light in the reciprocal direction. In various embodiments, a constraint for the optimization is that the two separate calculations must converge to the same metasurface design over time. For example, the same shape parameters for the metamaterial structures must be determined.

In various embodiments, a forward adjoint optimization process is run in parallel and/or intermittent with a reciprocal adjoint optimization process with a constraint that determined shape parameters in the forward and reciprocal processes must converge to the same shape parameters.

In various embodiments, during the forward adjoint optimization process, the placement parameters are determined using the forward incident beam. For example, in a focusing metasurface, when the forward incident beams are in parallel, the elevation and azimuth angles and the polarization parameters are known and the same for all the metamaterial structures. An iteration of the adjoint optimization process is performed in the forward direction and the shape parameters are determined.

However, in various embodiments, before the shape parameters are updated based on the determined gradient for the metamaterial structures, an adjoint optimization in the reciprocal direction is performed. In the example of the focusing metasurface, the incident beam in the reciprocal direction is a diverging beam and the target field is the collimated beam. The placement parameters for various metamaterial structures of the metasurface now may have a wide range of values because the incident beam is diverging and is not incident on all metamaterial structures on the metasurface at the same angle.

Therefore, the adjoint optimization is performed in the forward and reciprocal directions using the master design library that includes the placement parameters. The gradient for the metamaterial structures in the forward direction, and the gradient in the reciprocal direction for the metamaterial structures are determined and the adjoint optimization iterates the metasurface design and proceeds to the next loop. However, since the metasurface is the same device for both directions, the determined shape parameters for both directions need to converge.

Therefore, in various embodiments the adjoint optimization is performed for both forward and reciprocal directions using the known placement parameters and includes the constraint that the shape parameters in both forward and reciprocal directions are the same. In various embodiments, the iterations of the adjoint optimization in the forward and reciprocal directions are subject to the constraint that the shape parameters must converge to the same parameters for the forward and reciprocal directions.

In various embodiments, the placement parameters are fixed for each of the forward and reciprocal directions are determined using any of the light manipulation function, phase curvature, and/or the phase mask of the metasurface.

In various embodiments, while the adjoint optimization is performed, two calculations are completed using two different library mappings, as described above for the forward and reciprocal directions, and two gradients are calculated (as part of the adjoint optimization procedure). However, the metasurface shape map (the metamaterial structure shape parameters) remains the same for both calculations in the forward and reciprocal directions. The two gradients may then be evaluated together (e.g., using a weighted average, etc.) to calculate changes that need to be made to the metasurface shape map (that is kept the same for both directions) between each iteration.

Therefore, in various embodiments, from the beginning of the adjoint optimization it is asserted that the array of shapes is the same for the forward and reciprocal calculations. Therefore after a gradient for metamaterial structures in the forward direction and a gradient for metamaterial structures in the reciprocal direction are determined, information from both of those gradients are used to make a single set of changes to the shape parameters of the metamaterial structured of the metasurface.

Therefore, in various embodiments, the adjoint optimization considers both forward calculations and reciprocal calculations but at every iteration, the metasurface shape design is the same for both calculations. So rather than to allow them to start as different designs and converge to the same design, the shapes are forced to always remain the same.

In example embodiments, adjoint optimization allows for evaluating the response of the entire metasurface by evaluating how closely the target field is achieved using interim shape parameters. In some examples, the adjoint optimization is an aggregate optimization because the effects of the entire metasurface is taken into account. In example embodiments, the aggregate optimization therefore may account for the responses of the elements that are placed at a distance from each other on the overall design and function of the metasurface.

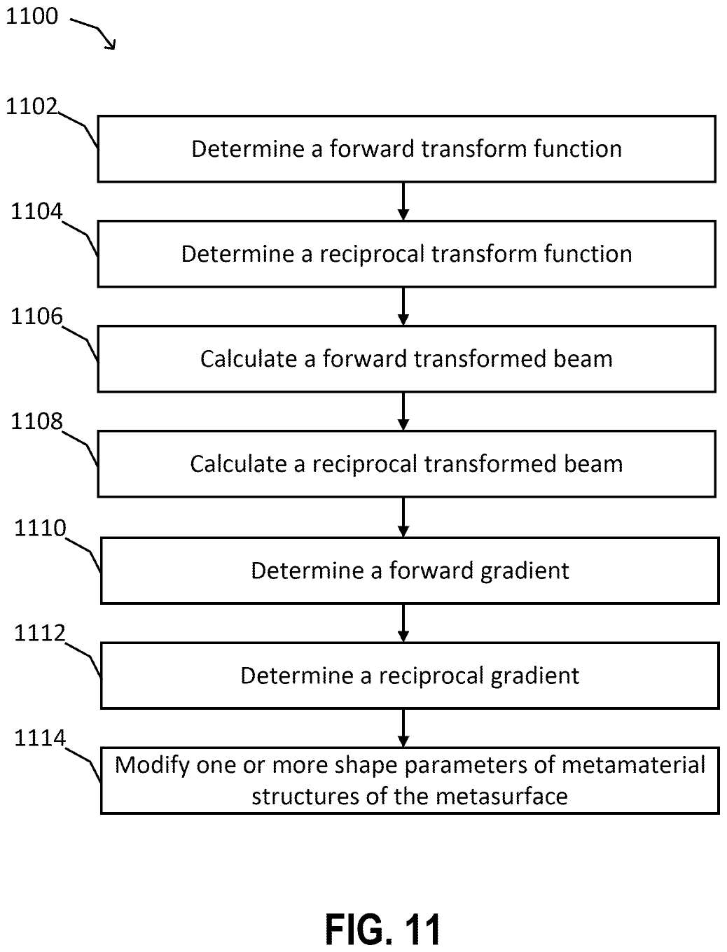

FIG. 11 is a flowchart illustrating a method 1100 for designing a metasurface according to various embodiments herein. In various embodiments, at step 1102, the computing entity 10 determines a forward transform function for one or more metamaterial structures of the metasurface. At step 1104, the computing entity 10 determines a reciprocal transform function for the one or more metamaterial structures of the metasurface. At step 11-6, the computing entity 10 calculates a forward transformed beam by transforming a field of a forward incident beam according to the forward transform function. At step 1108, the computing entity 10 calculates a reciprocal transformed beam by transforming a field of a reciprocal incident beam according to the reciprocal transform function.

At step 1110, the computing entity 10 determines a forward gradient. In various embodiments, the computing entity 10 compares the forward transformed beam with a forward target beam and determine a forward gradient using the comparison.

At step 1112, the computing entity 10 determines a reciprocal gradient. In various embodiments, the computing entity 10 compares the reciprocal transformed beam with a reciprocal target beam and determine a reciprocal gradient using the comparison.

At step 1114, the computing entity 10 modifies one or more shape parameters of metamaterial structures of the metasurface using the forward gradient and the reciprocal gradient.

In various embodiments, the forward gradient maps to a forward shape gradient in one or more shape parameters of the one or more metamaterial structures of the metasurface and the reciprocal gradient maps to a reciprocal shape gradient in one or more shape parameters of the one or more metamaterial structures of the metasurface. In various embodiments, the mapping may be a unity function.

In various embodiments, the method 1100 may further determine forward shape parameters of the metamaterial structures of the metasurface using the forward gradient. The method 1100 may determine reverse shape parameters of the metamaterial structures of the metasurface using the reverse gradient. The method 1100 may determine a shape convergence gradient, wherein the shape convergence gradient is a difference between the forward shape parameters and the reciprocal shape parameters for each metamaterial structure of the metasurface.

In various embodiments, the method 1100 may further iteratively repeat the determining of the forward and reverse shape parameters, and determining the shape convergence gradient for each metamaterial structure of the metasurface until a difference between forward transformed beam and the forward target beam is optimized and a difference between reciprocal transformed beam with and the reciprocal target beam is optimized. In various embodiments, as further described below, the difference between the forward transformed beam and the forward target beam, and the difference between reciprocal transformed beam and the reciprocal target beam are optimized when the shape parameters are the same in the forward and reciprocal directions, or the shape convergence gradient is zero.

In various embodiments, the method 1100 may optimize the design of the metasurface by modifying the one or more metamaterial structures of the metasurface using the forward gradient and the reciprocal gradient such that a difference between forward transformed beam and the forward target beam is optimized and a difference between reciprocal transformed beam with and the reciprocal target beam is optimized.

In various embodiments, the modification comprises modifying the forward and reciprocal shape parameters. In various embodiments, the method 1100 includes minimizing the shape convergence gradient, prioritizing the minimizing of the shape convergence gradient in iteratively repeating the determining of the forward and reverse shape parameters, and finalizing the optimization when the shape convergence gradient for each metamaterial structure of the metasurface is zero.

In various embodiments, the method 1100 includes equating forward shape parameters of the metamaterial structures of the metasurface with the reciprocal shape parameters of the metamaterial structures of the metasurface.

In various embodiments, the method 1100 includes optimizing the design of the metasurface by modifying the one or more metamaterial structures of the metasurface using the forward gradient and the reciprocal gradient such that a combination of the forward gradient and the reciprocal gradient is minimized.

In various embodiments, the modification of the one or more metamaterial structures of the metasurface includes modifying the equal forward and reciprocal shape parameters of each metamaterial structure of the metasurface using a combination of the forward gradient and the reciprocal gradient. In various embodiments, the combination is a weighted average. In various embodiments, the combination includes uneven weighting of the forward and reciprocal gradients. For example, a weighted average of the determined forward and reciprocal gradients are used to make the same change to the shape parameters of one or more metamaterial structures of the metasurface.

As described above, in various embodiments, a metasurface including a plurality of metamaterial structures, is designed and or optimized. For example, the metasurface may perform the functions of manipulating signals, such as light, for applications in quantum computers, light detection and ranging systems (Lidar), cameras, etc.

### Technical Problem and Technical Advantages

Optimization of metasurfaces may require use of a modeled library of metasurfaces. However, in various approaches that has previously been used, computationally modeling a large area metasurface may be computationally prohibitive because they take too much computational memory and time.

Various embodiments provide technical solutions to technical problems related to the computationally intractability of designing metasurfaces that have accurate responses (e.g., the response of the metasurface is accurately modeled). Various embodiments provide systems and method of optimization of metasurfaces without the computationally prohibitive modeling. These various technical solutions provide for optimization and development of metasurfaces including metasurfaces for example with 10×10 micron dimensions or larger in a computationally feasible manner. These solutions further avoid prohibitive memory requirements and significant processing costs of large metasurface array modeling while providing metasurface models that more accurately predict the behavior of respective metasurfaces.

### Example Computing Entity

FIG. 9 provides an illustrative schematic representative of an example computing entity 10 that can be used in conjunction with embodiments of the present invention. In various embodiments, a computing entity 10 may be configured to allow a user to provide input to a quantum computer (e.g., via a user interface of the computing entity 10) and receive, display, analyze, and/or the like output from the quantum computer. In various embodiments, the computing entity 10 may be configured to compute any steps or computations provided in according with various embodiments of the present disclosure.

As shown in FIG. 9, a computing entity 10 can include an antenna 12, a transmitter 14 (e.g., radio), a receiver 16 (e.g., radio), and a processing element 22 that provides signals to and receives signals from the transmitter 14 and receiver 16, respectively. The signals provided to and received from the transmitter 14 and the receiver 16, respectively, may include signaling information/data in accordance with an air interface standard of applicable wireless systems to communicate with various entities, such as a controller, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1×(1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 may comprise a network interface 28 for interfacing and/or communicating with another entity, device, or module, for example a controller, memory, user, etc. For example, the computing entity 10 may comprise a network interface 28 for providing executable instructions, command sets, and/or the like for receipt by the other entity, device, or module and/or receiving output and/or the result of a processing the output provided by the other entity, device, or module. In various embodiments, the computing entity 10 and the other entity, device, or module may communicate via a direct wired and/or wireless connection and/or via one or more wired and/or wireless networks.

The computing entity 10 may also comprise a user interface device comprising one or more user input/output interfaces (e.g., a display 18 and/or speaker/speaker driver coupled to a processing element 22 and a touch screen, keyboard, mouse, and/or microphone coupled to a processing element 22). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 20 (hard or soft), a touch display, voice/speech or motion interfaces, scanners, readers, or other input device. In embodiments including a keypad 20, the keypad 20 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 26 and/or non-volatile storage or memory 24, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### CONCLUSION

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method for designing a metasurface, the method comprising:
selecting a first metamaterial structure of a plurality of metamaterial structures of the metasurface;
generating a forward light propagation model for the first metamaterial structure, using a light manipulation function for the metasurface;
generating a reciprocal light propagation model for the first metamaterial structure using the light manipulation function for the metasurface;
determining a first electromagnetic response difference between the forward light propagation model and the reciprocal light propagation model; and
determining a first property range of the first metamaterial structure such that the first electromagnetic response difference is optimized.

2. The method of claim 1, wherein the light manipulation function of the metasurface comprises any of refractive and/or reflective light manipulation function.

3. The method of claim 2, wherein the reciprocal light propagation model models an interaction of light propagating in a reversed direction with the first metamaterial structure and the forward light propagation model models the interaction of light propagating in a forward direction with the first metamaterial structure, wherein in the forward light propagation model a forward angle of light remains unchanged and in the reciprocal light propagation model a reciprocal angle of light remains unchanged, wherein the reciprocal angle is determined using the light manipulation function for the metasurface and the forward angle.

4. The method of claim 2, wherein any of the refractive or reflective light manipulation functions comprises a light focusing and/or collimating function.

5. The method of claim 1, wherein the electromagnetic response comprises phase delay, amplitude, or polarization.

6. The method of claim 1, wherein optimizing the electromagnetic response difference comprises minimizing an aggregate performance metric of the metasurface.

7. The method of claim 1, wherein the first property range of the first metamaterial structure comprises any of a first shape and/or dimensions range of the first metamaterial structure.

8. The method of claim 1, wherein the first metamaterial structure is located at a periphery of the metasurface.

9. The method of claim 1, further comprising:
selecting a second metamaterial structure of a plurality of metamaterial structures;
generating the forward light propagation model for the second metamaterial structure;
generating the reciprocal light propagation model for the second metamaterial structure using the light manipulation function for the metasurface;
determining a second electromagnetic response difference between the forward light propagation model and the reciprocal light propagation model; and
determining a second property range of the second metamaterial structure such that the second electromagnetic response difference is optimized.

10. The method of claim 9, further comprising:
determining a first property value within the first property range, and a first location for the first metamaterial structure on a first unit cell of the metasurface; and
determining a second property value within the second property range, and a second location for the second metamaterial structure on a second unit cell adjacent to the first unit cell, wherein the first and second property values and locations are determined to meet geometrical constraints of the metasurface.

11. The method of claim 10, wherein the geometrical constraints comprise any of a distance between the first and second metamaterial structures and/or a fill fraction of a local region.

12. An apparatus comprising at least one processor and a memory storing computer-executable instructions, the computer-executable instructions configured, when executed by the at least one processor, to cause the apparatus to perform the method of claim 1.

13. A computer program product comprising at least one non-transitory computer-readable medium storing computer-executable instructions, the computer-executable instructions configured, when executed by a processor of an apparatus, to cause the apparatus to perform the method of any of claim 1.

14. A method for designing a metasurface, the method comprising:
selecting a reference metamaterial structure of a plurality of metamaterial structures of the metasurface;
determine a reference forward phase delay versus a property of the reference metamaterial structure for a forward incident angle;
determine a reference reciprocal phase delay versus the property of the reference metamaterial structure for a reverse incident angle; and
determine the property of the reference metamaterial structure such that a difference between the forward phase delay and the reciprocal phase delay is optimized,
wherein the forward phase delay and the reciprocal phase delay are offset with a fixed phase value.

15. The method of claim 14, comprising determining the forward incident angle and the reverse incident angle using a phase mask of the metasurface.

16. The method of claim 15, comprising determining the phase mask of the metasurface using a light manipulation function for the metasurface.

17. The method of claim 14, comprising selecting the reference metamaterial structure such that a difference between the forward incident angle and the reciprocal incident angle is minimized.

18. The method of claim 17, comprising determining properties of another metamaterial structure by referencing a forward phase delay of the other metamaterial structure with the reference forward phase delay and refencing the reverse phase delay of the other metamaterial structure with the reference reverse phase delay.

19. The method of claim 19, comprising iteratively repeating the determining properties of other metamaterial structures until the metasurface is optimized.

20. A method for designing a metasurface, the method comprising:
determining an optical response of a metamaterial structure of the metasurface for each value of the values for one or more placement parameters of the metamaterial structure, while keeping one or more global parameters of the metamaterial structure constant;
determining, for each of the values of the one or more placement parameters, the optical response of the metamaterial structure for each value of the values for one or more shape parameters of the metamaterial structure, while keeping the one or more global parameters of the metamaterial structure constant; and
recording the optical response with respect to each of the values of the one or more placement parameters and each of the one or more shape parameters.

21. The method of claim 20 comprising keeping the global parameters constant for all the metamaterial structures of the metasurface.

22. The method of claim 21, wherein the global parameters comprise height, local fill fraction, and/or wavelength associated with each metamaterial structure.

23. The method of claim 20, wherein the placement parameters comprise:
a forward incident angle of a forward optical beam on the metamaterial structure of the metasurface, wherein the forward incident angle is determined using an optical manipulation function of the metasurface; and
a reciprocal incident angle of a reciprocal optical beam on the metamaterial structure of the metasurface, wherein the reciprocal incident angle of the optical beam is determined using the optical manipulation function of the metasurface.

24. The method of claim 23, wherein the placement parameters comprise:
a forward polarization of the forward optical beam on the metamaterial structure of the metasurface, wherein the forward polarization is determined using the optical manipulation function of the metasurface; and
a reciprocal polarization of the reciprocal optical beam on the metamaterial structure of the metasurface, wherein the reciprocal polarization is determined using the optical manipulation function of the metasurface.

25. The method of claim 20, comprising:
updating a metasurface master library using by recording the optical response with respect to each of the values of the one or more placement parameters and each of the one or more shape parameters; and
optimizing the metasurface in the forward and reciprocal directions using the master library by determining optimum values of the one or more placement parameters and optimum values of the one or more shape parameters that optimize an aggregate metric for the metasurface.

26. A method for designing a metasurface, the method comprising:
determining a forward transform function for one or more metamaterial structures of the metasurface;
determining a reciprocal transform function for the one or more metamaterial structures of the metasurface;
calculating a forward transformed beam by transforming a field of a forward incident beam according to the forward transform function;
calculating a reciprocal transformed beam by transforming a field of a reciprocal incident beam according to the reciprocal transform function;
comparing the forward transformed beam with a forward target beam and determine a forward gradient using the comparison;
comparing the reciprocal transformed beam with a reciprocal target beam and determine a reciprocal gradient using the comparison; and
modifying one or more shape parameters of metamaterial structures of the metasurface using the forward gradient and the reciprocal gradient.

27. The method of claim 26, wherein the forward gradient maps to a forward shape gradient in one or more shape parameters of the one or more metamaterial structures of the metasurface and the reciprocal gradient maps to a reciprocal shape gradient in one or more shape parameters of the one or more metamaterial structures of the metasurface.

28. The method of claim 27 comprising:
determining forward shape parameters of the metamaterial structures of the metasurface using the forward gradient;
determining reverse shape parameters of the metamaterial structures of the metasurface using the reverse gradient;
determining a shape convergence gradient, wherein the shape convergence gradient is a difference between the forward shape parameters and the reciprocal shape parameters for each metamaterial structure of the metasurface; and
iteratively repeating the determining of the forward and reverse shape parameters, and determining the shape convergence gradient for each metamaterial structure of the metasurface until a difference between forward transformed beam and the forward target beam is optimized and a difference between reciprocal transformed beam with and the reciprocal target beam is optimized.

29. The method of claim 28 comprising optimizing the design of the metasurface by modifying the one or more metamaterial structures of the metasurface using the forward gradient and the reciprocal gradient such that a difference between forward transformed beam and the forward target beam is optimized and a difference between reciprocal transformed beam with and the reciprocal target beam is optimized.

30. The method of claim 29 wherein the modification comprises modifying the forward and reciprocal shape parameters.

31. The method of claim 30 comprising:
minimizing the shape convergence gradient;
prioritizing the minimizing of the shape convergence gradient in iteratively repeating the determining of the forward and reverse shape parameters; and
finalizing the optimization when the shape convergence gradient for each metamaterial structure of the metasurface is zero.

32. The method of claim 26 comprising equating forward shape parameters of the metamaterial structures of the metasurface with the reciprocal shape parameters of the metamaterial structures of the metasurface.

33. The method of claim 32 comprising optimizing the design of the metasurface by modifying the one or more metamaterial structures of the metasurface using the forward gradient and the reciprocal gradient such that a combination of the forward gradient and the reciprocal gradient is minimized.

34. The method of claim 33 wherein the modification of the one or more metamaterial structures of the metasurface comprises modifying the equal forward and reciprocal shape parameters of each metamaterial structure of the metasurface.

35. The method of claim 34 wherein the combination is a weighted average of the forward gradient and the reciprocal gradient.
